(19) United States
(12) Patent Application Publication
(10) Pub. No.: US 2011/0037091 A1
(43) Pub. Date: Feb. 17, 2011

(54) PACKAGE FOR LIGHT EMITTING DIODE, LIGHT EMITTING DEVICE, AND LIGHT EMITTING DEVICE MANUFACTURING METHOD

(75) Inventor: Hiroshi Fushimi, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: C.I. KASEI COMPANY LIMITED, TOKYO (JP)

(21) Appl. No.: 12/989,301

(22) PCT Filed: Mar. 9, 2009
(86) PCT No.: PCT/JP2009/054971

§ 371 Date: Oct. 22, 2010

(30) Foreign Application Priority Data
Apr. 23, 2008 (JP) 2008-112373

(51) Int. Cl. H01L 33/60; H01L 33/48

(52) U.S. Cl. 257/98; 438/27; 257/E33.061; 257/E33.056

(57) ABSTRACT

The present invention relates to a light emitting diode package for mounting a light emitting diode, a light emitting diode device with the light emitting diode package mounting a vertical electrode type light emitting diode thereon and a manufacturing method for manufacturing the light emitting device.

The light emitting diode package of the invention comprises at least a molding, and a first clip 122 and a second clip 123 fitted on the molding. The molding has at least a first opening 1212 and a second opening 1213 formed in a bottom portion thereof. The molding also has a reflecting portion 1214 formed around the first opening 1212 and the second opening 1213 for reflecting light. The molding further has a fluorescent film member mounting portion 1113 formed integrally for mounting a fluorescent film member 116 in the opening of the reflecting portion 1214. The first clip 122 has a light emitting diode mounting projection formed substantially at the center portion thereof for mounting the light emitting diode and is made to engage resiliently with the molding at both ends thereof. The first clip 122 engages with the molding at both ends thereof. The second clip 123 has a bonding projection formed to engage resiliently with the molding at both ends thereof.

### TECHNICAL FIELD

This invention relates to a light emitting diode package for mounting at least one light emitting diode thereon, a light emitting device, and a light emitting device manufacturing method. The invention relates to a light emitting diode package having a structure able to deliver a large current to the light emitting diode, a light emitting device, a light emitting device manufacturing method.

The invention relates to a package for a light emitting diode comprising at least a substrate formed integrally inside a reflecting frame, an opening formed in the substrate, and a lead-shaped conductive member fitted in the opening, a light emitting device, and a light emitting device manufacturing method.

The invention relates to a package for a light emitting diode that has good heat dissipation property and high reliability through which a large current can be run by using solder to bond electrodes of a vertical electrode type light emitting diode to a lead-shaped conductive member via a metal member, a light emitting device, and a light emitting device manufacturing method.

### BACKGROUND ART

A conventional package for a light emitting diode, a light emitting device and a light emitting device manufacturing method are described in, for example, unexamined Japanese patent publication 2008-103401.

The above publication will be described as an example of the prior art.

FIG. 13(a) is a cross-sectional drawing showing a vertical electrode type light emitting diode mounted on a package, (b) is an enlarged drawing of (a), and (c) is a plan drawing of the package and vertical electrode type light emitting diode.

In FIG. 13(a) to (c), the package for a vertical electrode type light emitting diode of this example embodiment comprises at least metal substrates 132 and 134, a slit or insulating member 133 between the metal substrates 132 and 134, and a cylindrical reflecting member 136 that is mounted on the metal substrates 132 and 134 and which has a sloping reflecting surface formed by a reflecting film 1361 that widens upward. The metal substrate 132 is electrically isolated from the metal substrate 134 by the slit or insulating member 133.

The metal substrates 132 and 134 can be formed of copper or copper alloy, aluminum or aluminum alloy, or iron or iron alloy. When the metal substrates 132 and 134 are of copper, for example, the strength is increased by the inclusion of a minute amount of zinc.

When the metal substrates 132 and 134 are copper substrates, nickel plating is formed on the substrates, which is followed by the forming of silver plating, and masking for the forming of a layer of gold plating at the position where the vertical electrode type light emitting diode is placed.

The width of at least one side of the reflecting member 136 is shorter than the length of the slit or insulating member 133, and it is mounted on the metal substrates to correspond with the slit or insulating member 133.

The insulating member 133 may be packed with ceramic material, thermosetting resin having as its main component a single-liquid or double-liquid epoxy resin, or resin composed of silicon resin, or just space may be used to impart insulation. Because the cylindrical reflecting member 136 that widens upward is bonded to the metal substrates 132 and 134 by adhesive it can maintain the strength of the metal substrates 132 and 134 having the slit.

The transparent sealing resin used to pack the inside of the reflecting member 136 in which the vertical electrode type light emitting diode 131 is located may be an elastomer type.

In FIG. 13(a) and (b), a containment recess 1321 that can accommodate the vertical electrode type light emitting diode 131 is formed in the metal substrate 132. The vertical electrode type light emitting diode 131 is provided with an upper electrode 1311 and a lower electrode 1312.

The metal substrate 132 is bonded to the lower electrode 1312 of the vertical electrode type light emitting diode 131 by, for example, eutectic solder. A metal connection plate 135 is used to connect the upper electrode 1311 of the vertical electrode type light emitting diode 131 to the metal substrate 134 by means of eutectic solder, for example.

Regions corresponding to the inside of the reflecting member, described below, on the surface of the metal substrates 132 and 134 where there is no vertical electrode type light emitting diode 131 or metal connection plate 135, are plated with silver plating 1362, 1363, which efficiently reflects the light emitted by the vertical electrode type light emitting diode 131.

In FIG. 13(c), the upper electrode 1311 of the vertical electrode type light emitting diode 131 has an opening 1313 that is in the shape of the character ∥, from which portion light is efficiently radiated out. Instead of being in the shape of the character ∥, the opening 1313 may be in the shape of a ∥, [symbol] , or [symbol] character or the like.

The metal connection plate 135 has, for example, two connecting portions 1351 that connect with a part of the upper electrode 1311 of the vertical electrode type light emitting diode 131. The thickness and number of the connecting portions 1351 can be varied. Also, the metal substrate 134 side of the metal connection plate 135 has a large surface area that connects with the metal substrate 134.

Light exiting from the side portion 1314 of the vertical electrode type light emitting diode 131 is radiated out through the opening in the metal connection plate 135. The metal connection plate 135 is bonded to the upper electrode 1311 and the metal substrate 134 by, for example, eutectic solder. The strength of the eutectic solder bonding can be increased by gold plating each side of the connection.

Also, the light emitting device described in the prior art unexamined Japanese patent publication 2007-317896 comprises a package having a side and a bottom as well as a top with an opening, and a light emitting diode mounted on the bottom. The side of the package is comprised of a glass layer to which pigment is added to improve the color purity of light emitted by the light emitting diode.

In the light emitting device described by the unexamined Japanese patent publication 2007-317896, the light emitting diode electrode and the package electrode are connected by wire bonding. With wire bonding, there is a risk of the light emitting layer being damaged from the ultrasonic vibration used to connect the wire to the light emitting diode.

Also, there is a risk of the wire bonding connection being broken by heat generated by the flow of a large current. Moreover, in order to protect the light emitting layer of the light emitting diode and the wire bonding connection of the light emitting device, the package is packed with insulating material, but the insulating material causes a decrease in the emission efficiency of the light emitting diode.

In the light emitting device described by unexamined Japanese patent publication 2008-103401, it is necessary to interpose insulating material between the metal substrates. Also, the strength of the adhesion between the insulating material and the metal substrates is a problem.

### DISCLOSURE OF THE INVENTION

To resolve the above kind of problems, an object of the present invention is to provide a light emitting diode package that by using metal ribbon and solder to bond the light emitting diode electrodes and package electrodes can withstand ultrasonic vibration and thermal stress, maintain high strength and is easy to manufacture, a light emitting device, and a light emitting device manufacturing method.

An object of the present invention is to provide a light emitting diode package having good mass-producibility, due to the light emitting diode package and light emitting device being composed by just assembling a molding having an opening and a lead-shaped conductive member that fits into the opening.

An object of the present invention is to provide a light emitting diode package that is easy to be assembled and has good heat dissipation property. An object of the present invention is also to provide a light emitting diode package that, not being packed with sealing material, has good assembly and mass-producibility, and heat dissipation property, and can take a large current flow, is resistant to thermal stress and can maintain high strength, a light emitting device, and a light emitting device manufacturing method.

Since the light emitting diode package, light emitting device and light emitting device manufacturing method of this invention do not use wire bonding, there is no risk of the light emitting layer of the light emitting device being damaged by vibration being transmitted to the light emitting layer, and there is also no risk of the bonding connections between the light emitting device electrodes and gold wires being broken by vibration during transportation or use, so the need for packing with sealing material is eliminated.

In accordance with the present invention, the molding and clips can be die-formed readily and quickly, providing good mass-producibility as well as low cost.

Since in accordance with the present invention, solder instead of wire bonding or the like is used to bond the light emitting diode electrodes to the metal ribbon, the bonding portions remain highly reliable over an extended period of time, in addition to which there is no need to use packing material to seal the vertical electrode type light emitting diode, making it possible to obtain a light emitting device having low cost and good mass-producibility.

In accordance with the invention the connection between the upper electrode of the vertical electrode type light emitting diode connected to one of the clips fitted in the molding and the other clip is a connection that is made by, for example, a plate shaped or a ribbon shaped strip of metal, so it can take a large current flow and, in addition, has good heat dissipation property and can alleviate any thermal stress that is generated. In particular, since the invention uses solder and not wire bonding to make a connection, the connection and/or the light-emitting layer is not subjected to vibration, making it possible to obtain a light-emitting device having good performance.

In accordance with the invention, around the vertical electrode type light emitting diode is an air layer, not packing material, so heat dissipation property is good and light emission is not blocked, so the emission efficiency is good.

In accordance with the invention, the package, the first and second clips, the vertical electrode type light emitting diode, the metal ribbon, the solder and so forth can be readily and quickly assembled by being mounted by an automated robot. Also, after the first and second clips are pressed, they only need to be fitted onto the package, so the number of steps needed to form the light emitting diode package is small, making it possible to produce it readily and quickly at low cost.

Since in accordance with the invention it is composed of a ceramic molding or ceramic substrate wherein a reflecting frame and an opening formed inside the reflecting frame are integrally formed, and a conducting member that fits in the opening, assembly is easy, enabling a low cost light emitting diode package to be obtained.

In accordance with the invention, the connection between the upper electrode of the vertical electrode type light emitting diode, and the conductive member fitted in the opening of the ceramic molding or ceramic substrate is made using metal material, so assembly is easy, it can take a large current flow, and light is efficiently reflected.

In accordance with the invention, the upper electrode of the vertical electrode type light emitting diode and the conductive member are connected using a metal member, so the size of the bonding area is increased and the connection can be made using solder, so heat dissipation property is good and a large current flow is possible.

In accordance with the invention, the connection between the upper electrode of the vertical electrode type light emitting diode, the light emitting surface of which has fine ridges formed thereon, and the conductive member does not use wire bonding, so vibration is not imposed on the bonding portion and/or the light emitting layer, making it possible to obtain light emitting devices with few defects. The vertical electrode type light emitting diode having fine ridges formed on the light emitting surface not only reflects light efficiently, but does not need sealing resin, enabling the radiation of strong light.

In accordance with the invention, the ceramic molding or ceramic substrate comprising the package is formed of porous ceramic, so light reflected and diffused on the surface can be effectively utilized without forming a particular reflecting surface, enabling high reflectance.

In accordance with the invention, a light emitting diode package can be obtained by just fitting a conductive member in the ceramic molding or ceramic substrate having at least two openings, so there are few parts and assembly is facilitated, and the number of steps involved is reduced.

Since in accordance with the invention it is composed of a ceramic body in which a reflecting frame and an opening formed inside the reflecting framework are integrally formed, and a lead-shaped metal substrate that fits in the opening, assembly is easy, enabling a low cost light emitting diode package to be obtained.

In accordance with the invention, the upper electrode of the vertical electrode type light emitting diode and a lead-shaped connection substrate are connected by a ribbon-shaped metal member, so the size of the bonding area is increased and the connection can be made using solder, so heat dissipation property is good and a large current flow is possible.

In accordance with the invention, with just a few parts, that is, the reflecting frame, and a ceramic body having at least two openings to which a lead-shaped metal mounting substrate, a lead-shaped metal connection substrate and a metal member are connected, assembly is easy and the number of steps involved is reduced.

### BRIEF DESCRIPTION OF THE DRAWINGS

FIGS. 1(a) to (c) show a first example embodiment of the invention, with (a) being a plan view of the light emitting device, (b) being a cross-sectional view of the light emitting device, and (c) being a bottom view of the light emitting device.

FIG. 2 is a perspective assembly view for explaining the light emitting diode package of the first example embodiment of the invention.

FIGS. 3(a) to (c) show a second example embodiment of the invention, with (a) being a plan view of the light emitting device, (b) being a cross-sectional view of the light emitting device, and (c) being a bottom view of the light emitting device.

FIGS. 4(a) and (b) show a third example embodiment of the invention, with (a) being a plan view of a light emitting device in which a plurality of vertical electrode type light emitting diodes are connected in series, and (b) is a cross-sectional view of the light emitting diode.

FIG. 5 is a perspective view for explaining projecting portions of a conductive member of a fourth example embodiment of the invention.

FIG. 6(a) is an assembly perspective view for explaining the molding and clips of the package of a fifth example embodiment of the invention, and (b) is a plan view showing the clips fitted on the molding.

FIG. 7(a) is a plan view of the molding of the fifth example embodiment of the invention, (b) is a cross-sectional view along line A-A of the plan view, (c) is a cross-sectional view along line B-B of the plan view, (d) is a side view of (a), and (e) is a bottom view of (a).

FIG. 8 is a drawing for explaining a light-emitting device according to the fifth example embodiment in which a vertical electrode type light emitting diode is set in the package, with (a) being a bottom view and (b) a cross-sectional view along C-C.

FIGS. 9(a) to (d) show a sixth example embodiment of the invention, with (a) being a plan view of the ceramic body formed integrally with a reflecting frame. (b) is a cross-sectional view of the ceramic body, (c) is a front view for explaining the light emitting diode package, and (d) is a bottom view of the light emitting diode package.

FIG. 10 is an assembly perspective view for explaining the light emitting diode package in the sixth example embodiment of the invention.

FIG. 11 is a schematic explanatory drawing of a seventh example embodiment of the invention, showing another example in which a lead-shaped metal mounting substrate and a lead-shaped metal connection substrate are fitted into openings in the ceramic body.

FIGS. 12(a) and (b) are schematic explanatory drawings of an eighth example embodiment of the invention, showing another example in which a lead-shaped metal mounting substrate and a lead-shaped metal connection substrate are fitted into the openings in the ceramic body.

FIG. 13 is a drawing for explaining an example of the prior art, being a light emitting device having a vertical electrode type light emitting diode provided inside a reflecting frame.

### BEST MODE FOR CARRYING OUT THE INVENTION

A light emitting diode package comprises a ceramic body that integrally forms a reflecting frame and a substrate, and a lead-shaped metal substrate. The ceramic body comprises the reflecting frame and a substrate formed integrally inside the reflecting frame. The substrate has at least two openings formed inside the reflecting frame. The two openings are located at mutually opposed positions, and are formed with a recessed groove that communicates from the underside of the reflecting frame to the lower side end portion.

The lead-shaped metal substrate is fitted in the openings, the recessed grooves and the lower side end portions. Because the light emitting diode package comprises just the integrally formed ceramic body and the lead-shaped metal substrate that fits on the ceramic body, there are few manufacturing steps, and it can mass-produced at low cost by die forming. The ceramic body can also be made of synthetic resin. The number of openings may be three or more. Also, the shape of the openings is arbitrary, but it is necessary to give consideration to the shape for when the lead-shaped metal substrate is fitted.

Engaging portions are formed on outside end portions of the ceramic body of the light emitting diode package. The engaging portions consist of recesses and projections, with which claw portions provided on the outside end portion of the lead-shaped metal substrate engage. The claws can be made to face inwards or outwards. Resilience can be imparted to the lead-shaped metal substrate so that its resilience fits it into the engaging portions.

The resilient lead-shaped metal substrate fits into the outside end portion and an opening of the ceramic body of the light emitting diode package. As a claw portion is not formed on the end of the lead-shaped metal substrate, it is preferable to use adhesive when it is fitted on the ceramic body.

The light emitting diode package is comprised by at least a ceramic molding integrally formed with a reflecting frame, a bottom portion, a first opening and a second opening, and a first conductive member and a second conductive member fitted in the first opening and second opening. A first engaging portion and a second engaging portion are provided on side end portions of the reflecting frame. Also, the reflecting frame has an integrally formed bottom portion, and is formed in a state whereby a light emitting diode can be mounted on the bottom portion.

The catch portion at one end of the first conductive member engages with the first engaging portion, and a projecting portion formed with a projecting cross-section on the other end is fitted in the first opening. Similarly, a projecting portion formed with a projecting cross-section on one end of the second conductive member is fitted in the second opening, and the other end engages with the second engaging portion. Between the projecting portion and the engaging portion, the first conductive member and the second conductive member each has a horizontal portion that extends along the lower part of the ceramic molding.

The light emitting diode package can be obtained by simply fitting the first conductive member and the second conductive member formed to a prescribed shape into engagement with the ceramic molding formed to a prescribed shape, so productivity is high and few steps are involved, enabling a low-cost product to be obtained. Adhesive or the like can be used to hold the materials in place after fastening with the engaging portions.

The light emitting diode package differs on the point that the ceramic molding is composed of a ceramic substrate. The ceramic substrate can be readily formed by the ceramic molding, making it possible to provide a reflecting cover or frame having a desired shape.

The light emitting diode package differs on the point that, with respect to the ceramic molding and ceramic substrate, at least two or more sets of pairs of openings are formed in series. The light intensity can be increased by increasing the number of light emitting diodes of the light emitting diode package, in addition to which the light radiation can be made linear.

The light emitting diode package differs on the point that, with respect to the ceramic molding and ceramic substrate, at least two or more sets of pairs of openings are formed in parallel. The light intensity can be increased by increasing the number of light emitting diodes of the light emitting diode package, the spacing in the side-by-side direction can be reduced, enabling the radiation of linear light with increased light intensity.

The light emitting diode package forms a surface light source by forming a plurality of sets of pairs of first opening and a second opening in series and parallel.

On the light emitting diode package, the other end of the conductive member is provided with a claw shaped catch portion. Assembly is facilitated by the engagement of the claw shaped portion with the recess of the ceramic molding or the upper part or the like of the ceramic substrate, producing a secure light emitting diode package.

The conductive member of the light emitting diode package is a plate-like member bent so that one end and/or the other end is provided with at least one downward facing projecting portion having a cross-section in the shape of a [symbol] character. The conductive member is formed from resilient material, and when bent is fitted into the opening by the resilience.

In the light emitting diode package, the projecting portion of the conductive member having a cross-section in the shape of a [symbol] character is provided with a pendant portion in the front and back and sideways directions. Because the descending portion, with respect to the opening in the ceramic molding or ceramic substrate, is provided with descending portions along four sides, the descending portion fits securely into the openings due to the resilience.

In the light emitting diode package, under its own resilience, the conductive member expands outwards in the opening of the ceramic molding or the ceramic substrate, and at the lower side end portions, the force acts to contract it inwards, holding it securely together.

A recessed groove is formed in the underside of the ceramic molding and ceramic substrate of the light emitting diode package, into which recessed groove the horizontal portion of the conductive member fits. The recessed groove can be more effectively used by using the resilience of the conductive member and adhesive to more securely affix the ceramic molding and the ceramic substrate and the conductive member.

The light emitting diode package comprises at least a molding and a first clip and second clip engaged with the molding. Formed in the molding are at least a first opening and a second opening. Also formed in the molding is a reflecting portion that reflects light, around the first opening and second opening. The molding also has a fluorescent film member mounting portion formed integrally for mounting a fluorescent film member in the opening of the reflecting portion.

The first clip has a light emitting diode mounting projection formed at the substantially central portion thereof for mounting the light emitting diode and to make resilient engagement with the molding at both ends thereof. The first clip is made to engage with the molding at both ends thereof. The second clip has a bonding projection formed to engage resiliently with the molding at both ends thereof. The fit between the first opening and the second opening and the first and the second clip may be a snug fit or a loose fit. The first clip and the second clip are formed in three directions centering on the light emitting diode mounting projection and the bonding projection so that they do not hit against each other, and have engaging portions for resilient engagement with the molding. Part of the engaging portions may be used to form a flat electric power source connecting portion.

The bottom portion of the light emitting diode package is provided with two recessed groove portions. The first clip and the second clip are made to fit in the respective recessed groove portion so that they do not move out of place. The first clip and the second clip are conductive members and supply electric power to the light emitting diode mounted on the light emitting diode package.

Two recessed groove portions are provided on the side portion of the light emitting diode package molding. The end portions of the first clip and the second clip are made to engage with the recessed groove portions so that they do not move out of place. The recessed groove portions provided on the bottom portion and the side portion may be provided just on the bottom portion, just on the side portion, or on the bottom portion and side portion.

The molding of the light emitting diode package may be made of ceramic, of porous ceramic, or of heat-resistant synthetic resin. Light from the light emitting diode can be reflected by the internal surface of a molding that is composed of porous ceramic. The internal surface of a molding that is made of ordinary ceramic or heat-resistant synthetic resin has to be provided with a reflecting film or the like that reflects. The heat-resistant synthetic resin may be an engineering plastic.

Both ends of the first clip and the second clip of the light emitting diode package are folded over inwards to form inclined projections. The inwardly folded inclined projections have a springiness that provides a secure fit on the molding. The light emitting diode package of the invention can be readily and quickly assembled by just fitting the first clip and the second clip onto the molding. It is preferable for resilience to be imparted to the material of the first clip and the second clip.

The ends of the first clip and second clip form electric power supply terminals. Electric wiring can be readily implemented by connecting electric power supply wiring to one or both of the electric power supply terminals.

With the ends of the first clip and the second clip forming the electric power supply terminals at the bottom portion of the light emitting diode package, a large current can be supplied to the light emitting diode without distortion. Also, the electric power supply terminals provided at the ends of the first clip and the second clip project in mutually different directions so that there is no mutual contact between them.

In the light emitting diode package, the light emitting diode mounting projection and the bonding projection of the first clip and second clip have engaging portions at each end thereof that resiliently engage with the molding. Also, the light emitting diode mounting projection and the bonding projection are provided with engaging portions that resiliently engage with the molding in mutually different directions that are orthogonal to the end portions thereof. The engaging portions are formed folded inwards and resiliently engage with the molding. That is, the light emitting diode mounting projection and the bonding projection are made to engage with the molding at three points, so the mounting is secure and stable.

Also, on the light emitting diode mounting projection and the bonding projection, the engaging portions formed in mutually different directions that are orthogonal to the end portions thereof may be provided, for example, with an engagement piece that can be folded back to the center and the end portions made into flat electric power supply terminals. Also, the light emitting diode mounting projection and the bonding projection are provided with the engagement piece and the electric power supply terminals at three points, so that when the light emitting device is installed, the mounting can be made stable and the distance to the wiring in any direction can be minimized.

The lead-shaped metal mounting substrate and the lead-shaped metal connection substrate of the light emitting device extend from the end portion to the lower part of the ceramic body. Since the light emitting device can be connected with the end portion by simply being placed on the wiring of a printed circuit board, wiring can be readily done with no special wiring being necessary.

In the light emitting device, the ceramic body comprises the reflecting frame, and a substrate formed integrally inside the reflecting frame. The substrate has at least two openings inside the reflecting frame, which are located at mutually opposed positions and are formed with a recessed groove that communicates from the underside of the reflecting frame to the lower side end portion. The lead-shaped metal substrate is fitted in the openings, the recessed grooves and the outside end portions.

One of the openings may be made large and the other small, for example, with the openings communicating with the outside end portions of the ceramic body via recessed grooves. The ceramic body and the lead-shaped metal substrate are assembled just by being fitted together, and adhesive or the like may be used so that the light emitting components do not become displaced when they are mounted.

The lead-shaped metal substrate is composed of a lead-shaped metal mounting substrate and a lead-shaped metal connection substrate. The lead-shaped metal mounting substrate is composed of a mounting portion for mounting the vertical electrode type light emitting diode, and a narrow lead portion that fits in the recessed groove that runs from the mounting portion to the outside end portion of the ceramic body. The lead-shaped metal connection substrate is composed of at least a large-area connecting portion that connects with the upper electrode of the light emitting diode via a metal member, and a narrow lead portion that fits in the recessed groove that runs from the mounting portion to the outside end portion of the ceramic body.

The lower electrode of the vertical electrode type light emitting diode is soldered to the lead-shaped metal mounting substrate. The upper electrode of the vertical electrode type light emitting diode is connected by solder to the lead-shaped metal connection substrate. The metal member is preferably a plate shaped metal member having good conductivity. The soldering is done simultaneously using eutectic solder, for example.

There may be three or more openings. For example, each of the lead-shaped metal mounting substrates can be fitted in two openings, and the lead-shaped metal mounting substrate can be fitted in one opening located at a position in opposition to the above openings. Two vertical electrode type light emitting diodes mounted on respective lead-shaped metal mounting substrates can be connected in parallel by making common use of the lead-shaped metal connection substrate. The two vertical electrode type light emitting diodes can also be connected in series.

In the light emitting diode, the openings formed in the substrate in the ceramic body comprise a large internal surface region, a small surface region that connects with the large surface region, and a recessed groove formed in the lower part of the reflecting frame that connects with the small surface region and extends to the outside end portion. The large surface region of the lead-shaped metal mounting substrate and the lead-shaped metal connection substrate fit in the openings, the small area region fits in the recessed groove, and the end fits in the outside end portion of the ceramic body. Assembly of the reflecting frame and the lead-shaped metal substrate is simple, forming a configuration that is low cost and does not easily come apart.

In the light emitting diode, the mounting portion of the lead-shaped metal mounting substrate and the bonding portion of the lead-shaped metal connection substrate fit in the large area region formed inside the ceramic body. Also, the other ends of the lead-shaped metal mounting substrate and the lead-shaped metal connection substrate fit in the respective outside end portion of the ceramic body. The lead portions of the lead-shaped metal mounting substrate and the lead-shaped metal connection substrate fit in the recessed grooves formed in the lower part of the ceramic body.

The outer ends of the lead-shaped metal mounting substrate and the lead-shaped metal connection substrate can engage with the recesses or the projections provided on the outer wall of the ceramic body. The outer ends of the lead-shaped metal mounting substrate and the lead-shaped metal connection substrate and the recesses or the projections on the outer wall may be shaped so they do not come out of engagement.

Since in the light emitting device, the lead-shaped metal mounting substrate and the lead-shaped metal connection substrate can easily become displaced if they are only fitted in the openings and the recessed grooves, they are prevented from falling out by using adhesive therebetween.

In the light emitting device, the metal member is gold wire formed into a ribbon shape. Because the ribbon-shaped wire is formed into thin strips, it can take a large current flow, in addition to which, when the upper electrode of the vertical electrode type light emitting diode and the lead-shaped connection substrate are being connected, the length can be changed (absorbed), enabling the bonding area to be increased, facilitating mounting and making possible connections having high heat dissipation property and reliability. Also, as the metal member is in the form of a thin strip, it has a higher heat dissipation property than wire-shaped material. Moreover, gold wire formed into ribbon makes it easy to use large-area soldering, so there is none of the vibration produced by wire bonding, enabling bonding portions to be made stronger without damaging the light emitting diode.

The metal member used in the light emitting device may be copper ribbon that is nickel-plated, or copper that is gold- or silver-plated. This metal material can well be used in place of gold ribbon, in terms of its connectability and/or pliancy.

The metal member in the light emitting device can be copper and copper alloy plated with gold and/or silver, thereby at the same time achieving improved light reflection efficiency, heat dissipation property, and solder, particularly eutectic solder, wettability. By giving the metal member a thickness of 15 μm to 35 μm, preferably 20 μm to 30 μm, and a width of from 100 μm up to the width of the electrodes of the vertical electrode type light emitting diode, it can take a large current flow, heat dissipation property is improved, and the strength is also improved when it is used as an assembly member.

The reflecting frame of the light emitting device is of porous ceramic, and the reflecting frame itself forms the reflecting portion. The porous ceramic used is an alumina based ceramic, such as for example one that has a pore diameter of from 0.10 μm to 1.25 μm, or a porosity of 10% or more.

The reflecting frame of the light emitting device is provided with a fluorescent material containing film member, and by means of this fluorescent material containing film member, light radiated from the vertical electrode type light emitting diode is output as light of a desired color. The fluorescent material containing film member contains at least one fluorescent material that converts light emitted by the vertical electrode type light emitting diode to substantially visible light. The vertical electrode type light emitting diode is, for example, a light emitting diode that emits light in the blue to ultraviolet wavelength, which blue to ultraviolet wavelength light is absorbed and converted to other, visible light.

The light emitting device is comprised of at least a ceramic molding, a first conductive member and a second conductive member, a vertical electrode type light emitting diode, a metal member, solder that connects each of these parts, and fluorescent material containing film member. The ceramic molding is provided with a reflecting frame that radiates light from the vertical electrode type light emitting diode, a first engaging portion and a second engaging portion provided at both ends of the reflecting frame, a bottom portion formed integrally in the reflecting frame having the vertical electrode type light emitting diode and metal member, and a first opening and a second opening formed integrally in the bottom portion into which the first conductive member and second conductive member fit.

Projecting portions formed with a projecting cross-section on one end or the other end of the first conductive member and the second conductive member fit in the first opening and the second opening, and the other end or one end engages with the first engaging portion and second engaging portion. The lower electrode of the vertical electrode type light emitting diode is connected on the projecting portion provided on the first conductive member. The upper electrode of the vertical electrode type light emitting diode is connected via the metal member to the projecting portion provided on the second conductive member.

Solder is used to effect the connection between the projecting portion provided on the first conductive member and the lower electrode of the vertical electrode type light emitting diode, the connection between the upper electrode of the vertical electrode type light emitting diode and the metal member, and the connection between the metal member and the projecting portion provided on the second conductive member. The upper opening of the reflecting frame is provided with a fluorescent material containing film member. The light emitting device can be assembled readily and quickly by just soldering the connections of the ceramic molding, the vertical electrode type light emitting diode, the first and the second conductive members and the metal substrate, so productivity is improved, providing a low cost device.

The points of difference of the light emitting device are that the ceramic molding is a ceramic substrate, the vertical electrode type light emitting diode has fine ridges formed on the light emitting surface, and the vertical electrode type light emitting diode is totally covered by a cover member, formed with the whole surface thereof covered by the fluorescent material containing film member.

The light emitting device is made to have a linear or a surface light source by providing vertical electrode type light emitting diodes in series and/or parallel on a ceramic molding and/or ceramic substrate. When openings of the conductive members of the light emitting device are arranged serially, the light source becomes a relatively open linear shape, while when the openings are arranged in parallel, it becomes a linear shape in which the light sources have a small separation.

In the light emitting device, the vertical electrode type light emitting diodes are not individually covered; instead, a single cover is used to cover all of the vertical electrode type light emitting diodes, and a fluorescent material containing film member is formed over the whole surface of the cover. The light emitting device enables a line light source, like a fluorescent lamp, or a surface light source to be manufactured.

The ceramic body and the ceramic substrate and the conductive members of the light emitting device are bonded by adhesive. Using adhesive in addition to the inherent resilience of the conductive members provides a more secure assembly.

At least one vertical electrode type light emitting diode is mounted on the light emitting diode package of the light emitting device. A plurality of the vertical electrode type light emitting diodes may also be mounted in parallel on the package. The lower electrode of the light emitting diode is bonded to the light emitting diode mounting projection provided on the first clip. Also, the upper electrode of the vertical electrode type light emitting diode and the bonding projection of the second clip are connected by a metal ribbon.

The opening of the molding comprising the light emitting diode package is provided with a fluorescent film member. The fluorescent film member converts the vertical electrode type light emitting diode light to a specific wavelength to make it a desired color. The first clip and second clip used with the vertical electrode type light emitting diode are connected by a wide metal ribbon, which makes it possible to supply a large current and also increases the surface area, which reduces electrical resistance and provides good light reflectance and heat dissipation.

In the light emitting device, the light emitting diode mounting projection and the lower electrode of the vertical electrode type light emitting diode, the upper electrode of the vertical electrode type light emitting diode and the metal ribbon, and the metal ribbon and the bonding projection are connected by solder. Solder provides a stronger connection than wire bonding, high connection strength, and can take a large current flow, without damage to the light emitting portion caused by ultrasonic vibration or breakage of connections.

Because wire bonding is not used to make the connections in the light emitting device, the connection strength of each portion is high and there is no need to pack the inside of the package with insulating material, the space between the vertical electrode type light emitting diode and the fluorescent film member is an air layer. Also, since the light emitting device package is not packed with insulating material, heat dissipation is good, so a large current can be delivered to the vertical electrode type light emitting diode. The package structure of this invention, taken together with the use of metal ribbon and solder, makes it possible to use a large current, making it possible to obtain a high brightness light emitting device.

The method of manufacturing the light emitting device comprises the step of manufacturing the package and the step of manufacturing the light emitting components. In the package manufacturing step, a reflecting frame, a substrate formed integrally in the reflecting frame, at least two openings provided in the substrate, and a recessed groove in the openings that communicates with the lower side end portion are formed integrally on a green sheet. After this forming, the green sheet is sintered to form the ceramic body. A lead-shaped metal mounting substrate and a lead-shaped metal connection substrate are fitted into the openings, the recessed groove and the outside end portions of the ceramic body.

After solder has been placed on the mounting portion of the lead-shaped metal mounting substrate, the lower electrode of the vertical electrode type light emitting diode is put in place. After solder has been placed on the upper electrode of the vertical electrode type light emitting diode and the lead-shaped metal connection substrate, the metal member is mounted.

The lead-shaped metal mounting substrate, the lead-shaped metal connection substrate, the vertical electrode type light emitting diode and metal member are bonded on the ceramic body, for example by being heated by being passed through a reflow oven. If necessary, the fluorescent material containing film member is affixed to the reflecting frame. The metal member is formed of copper-titanium or phosphor bronze material having springiness, and has a thickness of from 100 μm to 1000 μm, and preferably 200 μm to 600 μm.

The method of manufacturing the light emitting device comprises the step of manufacturing the package and the step of manufacturing the light emitting components. In the package manufacturing step, at least two openings and the engaging portions are formed in the ceramic body or the ceramic substrate that forms the reflecting frame. After the green sheet has been formed, the ceramic openings and the engaging portions are sintered to form a ceramic. Conductive members having a projecting cross-sectional portion and engaging claw portions are formed to a shape that can engage with the openings and the engaging portions.

The light emitting components comprise the vertical electrode type light emitting diode, the upper light emitting surface of which has fine ridges formed thereon, the metal member, and solder. In the light emitting component manufacturing step, first, solder is placed between the lower electrode of the vertical electrode type light emitting diode and the projecting cross-sectional portion provided on the conductive member, between the upper electrode of the vertical electrode type light emitting diode and the metal member, and between the metal member and the projecting cross-sectional portion of the conductive member.

Then, the ceramic body or the ceramic substrate, the conductive member, the metal member and the vertical electrode type light emitting diode are heated by being passed through a reflow oven, for example, and after the solder is melted, the parts are bonded by cooling. Because solder is used to connect the conductive members and the electrodes of the vertical electrode type light emitting diode, via the metal member, no vibration or the like is imposed, so the yield can be raised.

After the completion of the step of manufacturing the package and the step of manufacturing the light emitting components, light emitting devices can be manufactured in various configurations by the provision of a cover member on the reflecting frame on which the fluorescent 2 u material containing film member is formed, with the interposing of an air space. That is, because in this invention there is no sealing resin on the light emitting surface of the vertical electrode type light emitting diode, there is no sealing resin between the fine ridges formed on the light emitting surface, so the brightness can be improved.

The light emitting diode package of this invention has a bottom portion provided with openings, a reflecting portion that reflects light, and a fluorescent film member mounting portion for mounting a fluorescent film member that are formed integrally, and can be readily assembled by just fitting clips in the openings, giving it good mass-producibility.

Details of example embodiments of the invention will now be explained with reference to the drawings.

### EXAMPLE EMBODIMENT 1

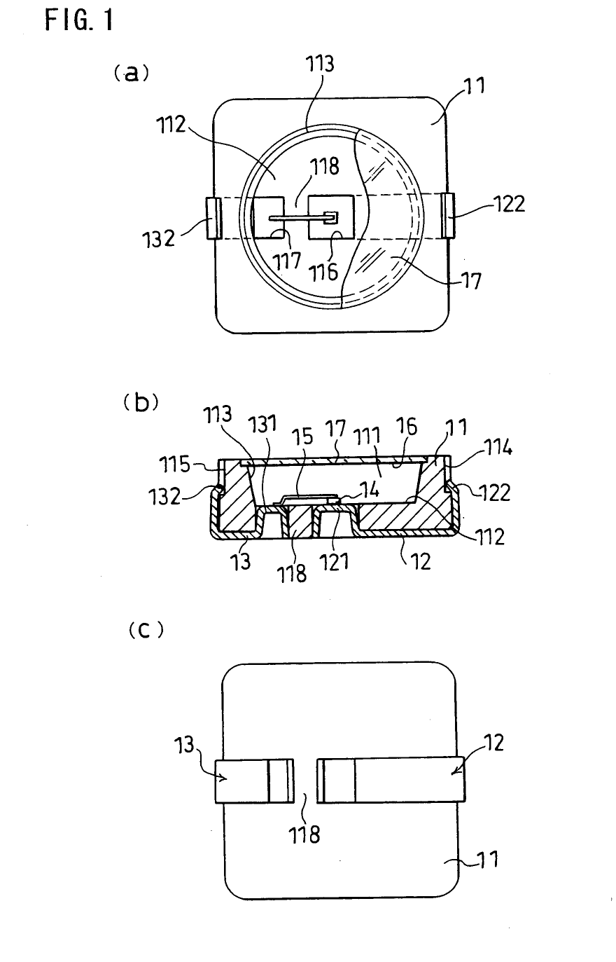

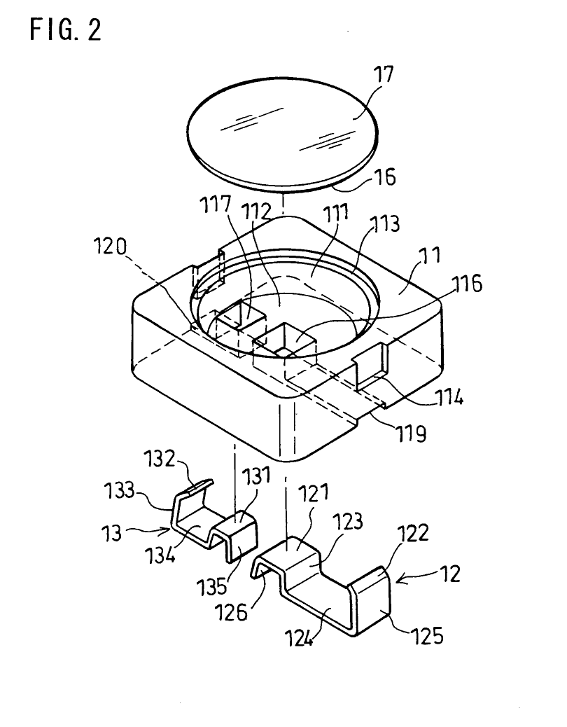

FIGS. 1(a) to (c) show a first example embodiment of the invention, with (a) being a plan view of the light emitting device, (b) being a cross-sectional view of the light emitting device, and (c) being a bottom view of the light emitting device. FIG. 2 is a perspective assembly view for explaining the light emitting diode package of the first example embodiment of the invention. In FIGS. 1(a) to (c) and FIG. 2, a light emitting diode package is comprised of at least a ceramic molding 11, and a first conductive member 12 and a second conductive member 13.

The ceramic molding 11 comprises a space 111 formed by a recessed portion, an inside bottom portion 112 that is the bottom portion of the space, a reflecting surface 113 formed around the inside bottom portion 112, a first opening 116 and a second opening 117 formed in the inside bottom portion 112, a first engaging portion 114 and a second engaging portion 115 formed at both ends, and recessed grooves 119 and 120 (see FIG. 2) formed in the bottom surface.

Catch portion 122 at one end of the first conductive member 12 engages with a first engaging portion 114 in the ceramic molding 11, and a projecting portion 121 at the other end formed into a projecting cross-section fits into the first opening 116. Similarly, the projecting portion 131 at one end of the second conductive member 13 formed into a projecting cross-section fits into the second opening 117, and the other end engages with the second engaging portion 115.

The first conductive member 12 and second conductive member 13 have horizontal portions 124 and 134 that extend along the underside of the ceramic molding between i) the projecting portions 121 and 131 and the first engaging portion 114 and second engaging portion 115. As shown in FIG. 2, the recessed grooves 119 and 120 are provided on the underside of the ceramic molding 11 which, when the first conductive member 12 and second conductive member are fitted therein, becomes a flat surface, as shown in FIG. 1(b). The first conductive member 12 and second conductive member 13 are electrically insulated from each other by a portion of the ceramic molding 11.

As shown in FIG. 1(b) and FIG. 2, the first conductive member 12 is integrally formed with a first catch portion 122, a pendant portion 125, a horizontal portion 124, a perpendicular portion 123, a projecting portion 121, and a pendant portion 126. Similarly, as shown in FIG. 1(b) and FIG. 2, the second conductive member 13 is integrally formed with a second catch portion 132, a pendant portion 133, a horizontal portion 134, a perpendicular portion, a projecting portion 131, and a pendant portion 135. While in the drawings the first engaging portion 114 and the second engaging portion 115 are formed as recesses, they can be formed as protruding portions with which the first catch portion 122 and second catch portion 132 engage.

As shown in FIGS. 1(a) and (b), the vertical electrode type light emitting diode 14 is mounted on the projecting portion 121 of the first conductive member 12 via solder (not shown). The metal member 15 is mounted on the upper electrode of the vertical electrode type light emitting diode 14 and the projecting portion 131 of the second conductive member 13 via solder. Then, the solder is heated to bond each part. The blue or ultraviolet light emitted by the vertical electrode type light emitting diode 14 is converted to white light via a fluorescent material containing film member 16 provided on the opening of the ceramic molding 11, and is radiated out from a cover 17. The vertical electrode type light emitting diode 14 has fine ridges formed on the light emitting surface thereof, enabling a lot of light to be radiated.

The light emitting diode package can be obtained at low cost by an assembly comprising just mounting the ceramic molding 11 formed into a prescribed shape, and the first conductive member 12 and the second conductive member 13, so productivity is high and there are few steps. Due to the metal member 15 being in the shape of a ribbon or thin strip shaped plate member, the light emitting device assembled by means of the light emitting diode package is able to take a large current flow, in addition to which, as soldering can be used, there is no need to pack the inside with resin material, so it can be made compact and the emission efficiency, heat dissipation property and vibration resistance improved. Also, because the vertical electrode type light emitting diode 14 has no upper sealing resin, there is no degradation in the radiation of the light produced by the fine ridges formed on the light emitting surface.

### EXAMPLE EMBODIMENT 2

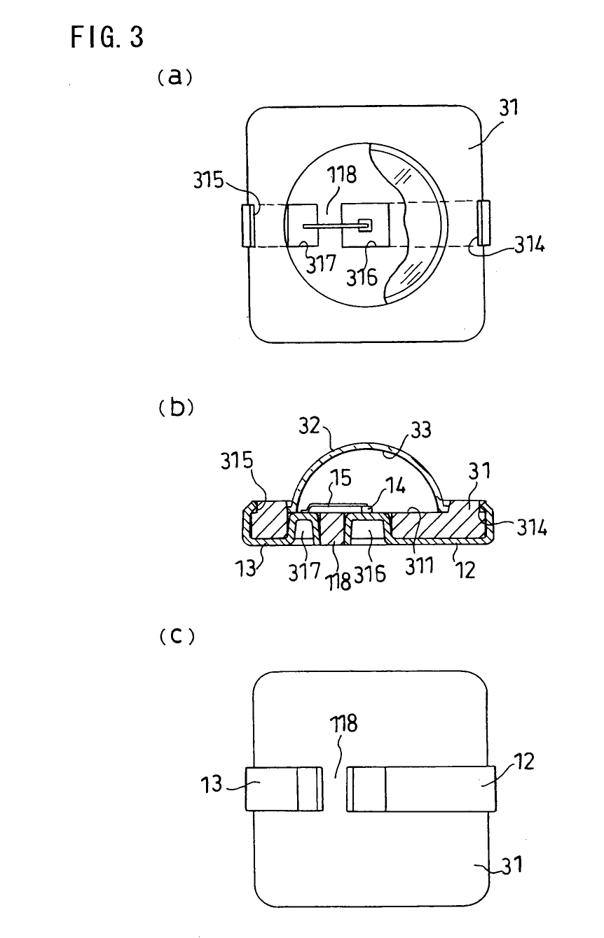

FIGS. 3(a) to (c) show a second example embodiment of the invention, with (a) being a plan view of the light emitting device, (b) being a cross-sectional view of the light emitting device, and (c) being a bottom view of the light emitting device. The points of difference between the light emitting device of the second example embodiment of FIGS. 3(a) to (c) and that of the first example embodiment are the ceramic substrate 31, and the hemispherical cover 32 with a fluorescent material containing film member 33 formed on the inside surface, provided over the ceramic substrate 31. The ceramic substrate 31 has a first opening 316 and a second opening 317 formed therein, and a first engaging portion 314 and a second engaging portion 315 formed at both ends.

The first conductive member 12 and the second conductive member 13, the first opening 316 and the second opening 317, the vertical electrode type light emitting diode 14, and the metal member 15 are the same as in the first example embodiment. A step is provided in the inside bottom portion 311 of the ceramic substrate 31, facilitating the attachment of the cover 32.

### EXAMPLE EMBODIMENT 3

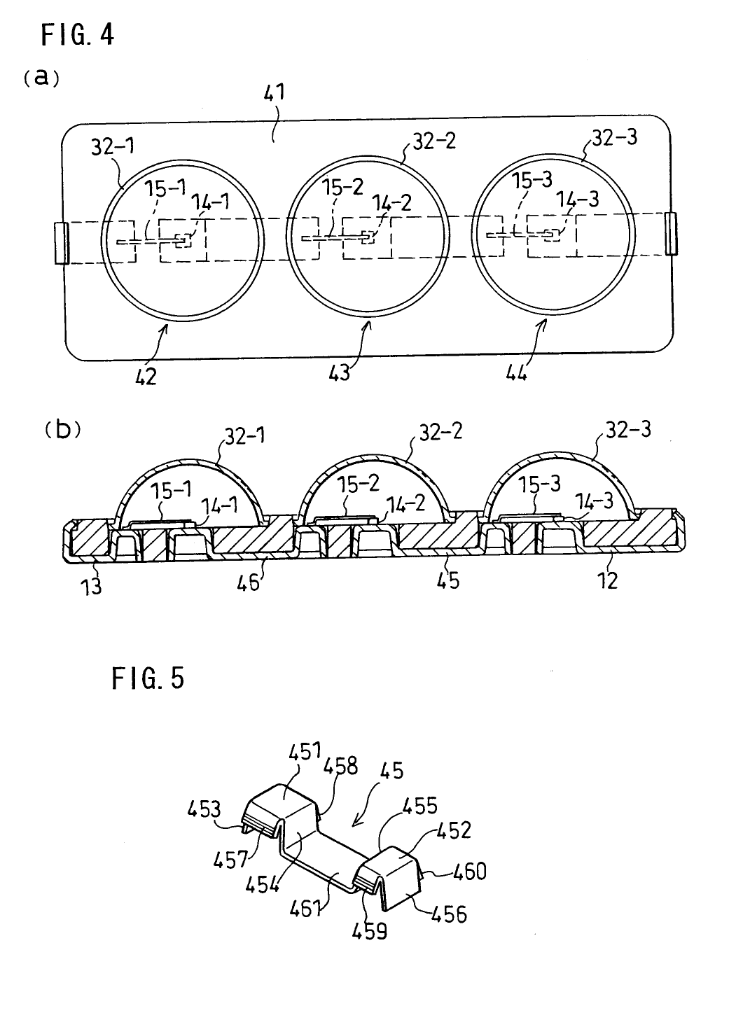

FIGS. 4(a) and (b) show a third example embodiment, of the invention, with (a) being a plan view of a light emitting device in which a plurality of vertical electrode type light emitting diodes are connected in series, and (b) is a cross-sectional view of the light emitting diode. In the third example embodiment of FIGS. 4(a) and (b), a plurality of the light emitting devices of the second example embodiment are connected in series on a single ceramic substrate 41. The first conductive member 12 and the fourth conductive member 13 of the second example embodiment are the same as those of the second example embodiment. A projecting portion provided at both ends of a second conductive member 45 and a third conductive member 46 fit in the respective openings.

Vertical electrode type light emitting diodes 14-1, 14-2, 14-3 are mounted on the projecting portions of the conductive members, and are bonded to the other projecting portions by metal members 15-1, 15-2, 15-3 and solder. The number of vertical electrode type light emitting diodes used is arbitrary. The light intensity of the light emitting diode package can be increased by increasing the number of vertical electrode type light emitting diodes, in addition to which the light radiation can be made linear. Also, the amount of light from the light emitting device in which the vertical electrode type light emitting diodes are connected in series can be adjusted by adjusting the length of the conductive members.

### EXAMPLE EMBODIMENT 4

FIG. 5 is a perspective view for explaining projecting portions of a conductive member of a fourth example embodiment of the invention. In the conductive member 45 of the fourth example embodiment, of FIG. 5, the projecting portions of the conductive members of the first to third example embodiments composed of two pendant pieces are provided with four pendant portions, forming a structure in which their resilience works when fitted into the openings.

That is, the conductive member 45 is composed of a horizontal portion 461 that fits in a recessed groove formed in the bottom portion of the ceramic molding or ceramic substrate, riser portions 454 and 455 that rise from the horizontal portion 461, projection portions 451 and 452 that extend from the riser portions 454 and 455, pendant portions 453 and 456 that descend down from the projection portions 451 and 452, and pendant portions 457, 458, 459 and 460 that descend down from the projection portions 451 and 452, and descend down in a direction that differs from that of the horizontal portion 461 and pendant portions 453 and 456.

By imparting resilience to the conductive member, the pendant portions provided in four directions form a solid fit in the openings. The conductive member can be affixed by the springiness and/or adhesive. The conductive member can be assembled readily and quickly by just fitting it in the openings.

In the above third example embodiment the vertical electrode type light emitting diodes were connected in series to form a linear light source. However, the vertical electrode type light emitting diodes can also be connected in parallel in a straight line in which the spacing between adjacent vertical electrode type light emitting diodes is made narrow. Furthermore, the vertical electrode type light emitting diodes can be connected in series and/or in parallel to form a surface light source.

### EXAMPLE EMBODIMENT 5

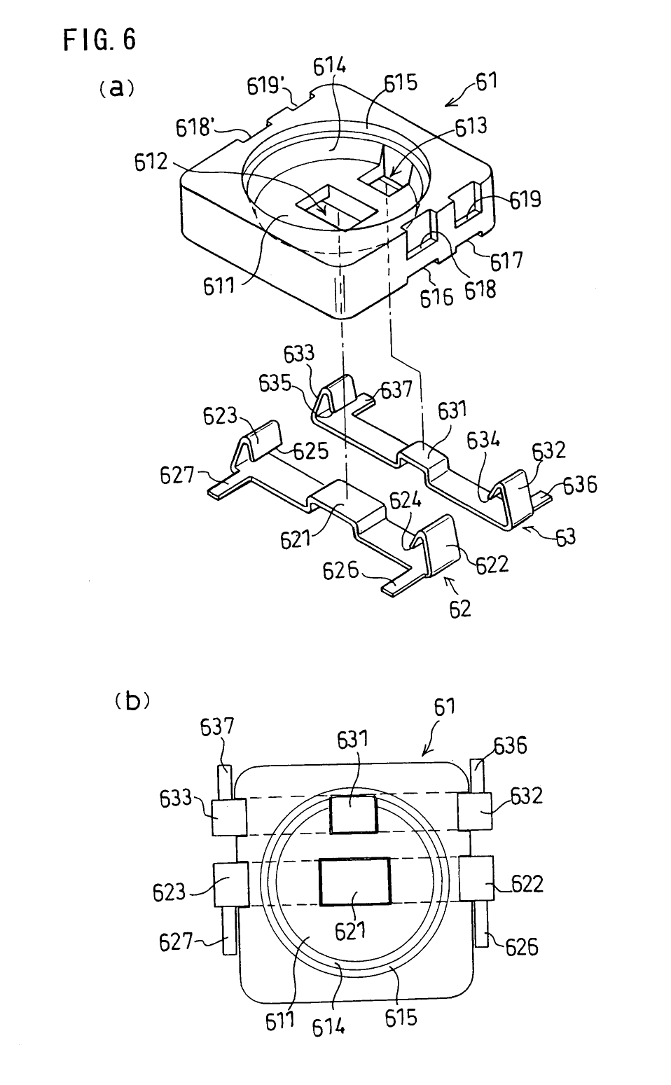

FIG. 6(a) is an assembly perspective view for explaining the molding and clips of the package of a fifth example embodiment of the invention, and (b) is a plan view showing the clips fitted on the molding. The package shown in FIG. 1(a) comprises a molding 61, and a first clip 62 and a second clip 63 that clip onto the molding 61. Provided in a substantially central part of a bottom portion 611 of the molding 61 are a first opening 612 and a second opening 613 into which the first clip 62 and the second clip 63 fit. The first opening 612 is formed in the central part of the molding 61.

Formed on the underside of the bottom portion 611 are recessed grooves 616 and 617 into which the first clip 62 and second clip 63 fit. The molding 61 also has a reflecting portion 614 that reflects light from the vertical electrode type light emitting diode that is provided on the side portion that extends from the bottom portion 611, and a fluorescent film mounting portion 615 to attach a fluorescent film member (not shown). The upper side part of the molding 61 is also provided with recessed side grooves 618, 618′, 619 and 619′ for engagement with the ends of the first clip 62 and the second clip 63.

In FIG. 6(a), a vertical electrode type light emitting diode mounting projection 621 is formed in the center of the first clip 62, and both ends thereof are bent up and folded back to form first engaging portions 622 and 623 to engage with the recessed side grooves 618 and 618′. Also, the first engaging portions 622 and 623 have first engaging ends 624 and 625 that engage with the lower part of the recessed side grooves 618 and 618′. The first engaging portions 622 and 623 and first engaging ends 624 and 625 are inclined inwards with respect to the package to impart resilience thereto.

Similarly, in FIG. 6(a), a metal ribbon connecting portion 631 is formed in the middle of the second clip 63, and both ends thereof are bent up and folded back to form second engaging portions 632 and 633 to engage with the recessed side grooves 619 and 619′. Also, the second engaging portions 632 and 633 have second engaging ends 634 and 635 that engage with the lower part of the recessed side grooves 619 and 619′. The second engaging portions 632 and 633 and the second engaging ends 634 and 635 are inclined inwards with respect to the package to impart resilience thereto. Also, the first clip 62 and the second clip 63 are provided at their lower ends with first electric power supply terminals 626 and 627 and second electric power supply terminals 636 and 637 that project in mutually opposed directions.

The molding 61 can be the-formed of ceramics, porous ceramics or heat-resistant synthetic resin. In the case of ceramics, ceramic powder or green sheet can be the-formed or the like, then sintered. The first clip 62 and the second clip 63 can be manufactured by the press-forming of a conductive material such as phosphor bronze. The first clip 62 is fitted on to the molding 61 with the light emitting diode mounting projection 621 fitting into the first opening 612, and the first engaging ends 624 and 625 at both ends engaged with the lower part of the recessed side grooves 618 and 618′.

The second clip 63 is fitted on to the molding 61 with the metal ribbon connecting portion 631 formed in the center part thereof fitted in the second opening 613 in the bottom portion thereof, and the second engaging ends 634 and 635 at both ends engaged with the lower part of the recessed side grooves 619 and 619′.

FIG. 6(b) is a plan view showing when the molding 61 and the first clip 62 and the second clip 63 are assembled together. The first clip 62 and second clip 63 are provided with first electric power supply terminals 626 and 627 and second electric power supply terminals 636 and 637 that project in mutually different directions. The size and shape of the molding 61, the first and second openings 612 and 613, the light emitting diode mounting projection 621, the metal ribbon connecting portion 631, the first engaging portions 622 and 623, the first engaging ends 624 and 645, the second engaging portions 632 and 633, the second engaging ends 634 and 635, the first electric power supply terminals 626 and 627 and the second electric power supply terminals 636 and 637 are arbitrary.

### EXAMPLE EMBODIMENT 5

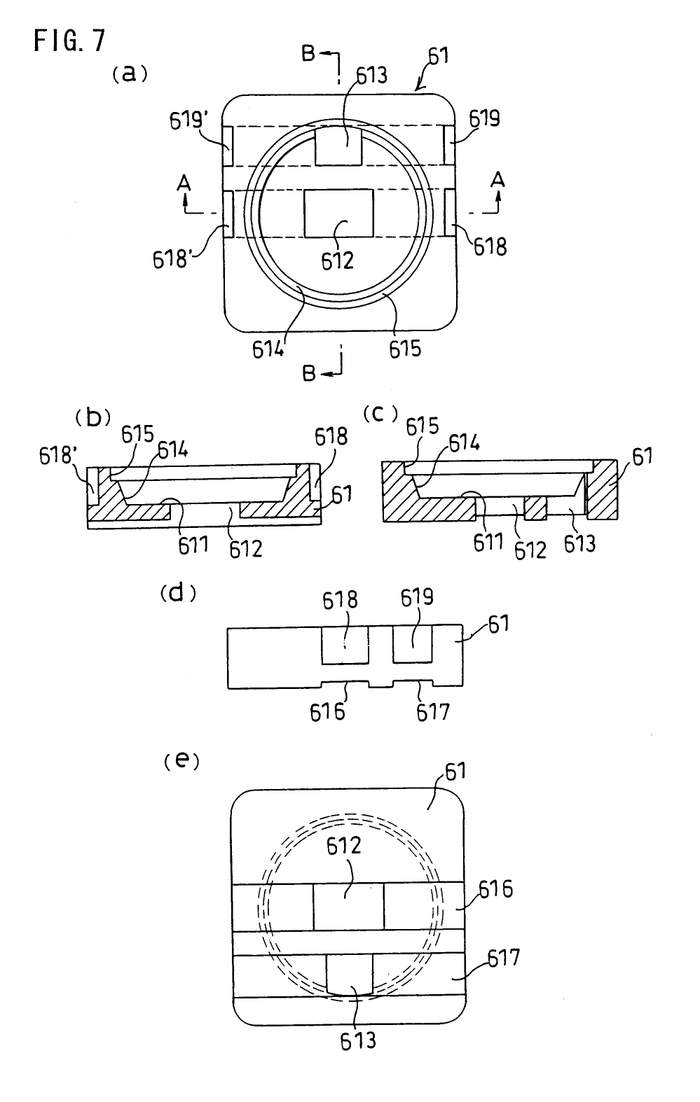

FIG. 7(a) is a plan view of the molding of the fifth example embodiment of the invention, (b) is a cross-sectional view along line A-A of the plan view, (c) is a cross-sectional view along line B-B of the plan view, (d) is a side view of the plan view (a), and (e) is a bottom view of the plan view (a). The molding 11 may be formed of a silicone resin, an epoxy resin alumina, a composite ceramic of alumina and glass, or porous ceramic or other such material.

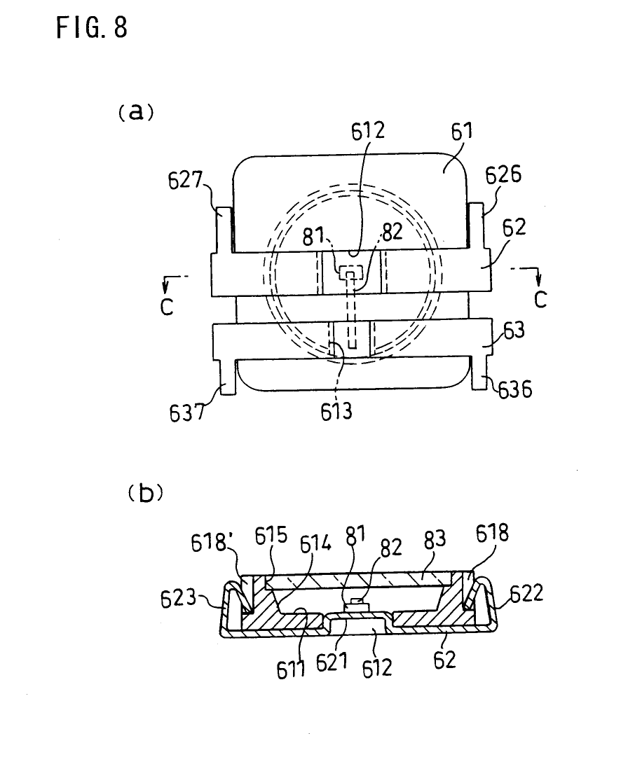

FIG. 8 is a drawing for explaining a light-emitting device according to the fifth example embodiment in which a vertical electrode type light emitting diode is set in the package, with (a) being a bottom view and (b) a cross-sectional view along C-C. After the molding 61 is assembled with the first clip 62 and second clip 63, the lower electrode of the vertical electrode type light emitting diode 81 is bonded to the light emitting diode mounting projection 621 of the first clip 62. Then, the upper electrode of the vertical electrode type light emitting diode 81 is bonded to metal ribbon 82. The other end of the metal ribbon 82 is bonded to the metal ribbon connecting portion 613 of the second clip 63. A fluorescent film member 83 that is mounted on a fluorescent film member mounting portion 615 provided on the opening of the molding 61 converts the wavelength of light from the vertical electrode type light emitting diode to light of a desired color. Connections at the connecting portions can be simultaneously effected by placing solder on the locations and heating it.

The metal ribbon has a thickness of 25 μm and a width of from 150 μm to 200 μm, for example, and the length thereof can be varied. The metal ribbon is formed of gold strip, giving it good conductivity and enabling it to carry a large flow of current. Moreover, because the ribbon reflects light well, the light is irradiated efficiently to the outside without producing shadows.

The vertical electrode type light emitting diode 81 has at least an active layer between a p-type gallium nitride semiconductor layer and an n-type gallium nitride semiconductor layer. The gallium nitride system vertical electrode type light emitting diode 81 has an upper surface light-emitting portion and an upper electrode on one of the semiconductor layers, and the lowermost layer of the other semiconductor layer has a lower electrode that is bonded to the light emitting diode mounting projection 621 of the first clip 62. The upper surface of the gallium nitride system vertical electrode type light emitting diode has fine ridges formed on the electrode upper surface, enabling a large current to be used to obtain high brightness.

The package may be a square one measuring, for example, 10 mm by 10 mm, and the size of the light emitting diode 81 may be, for example, 1.0 mm by 1.0 mm by 0.14 mm thick.

### EXAMPLE EMBODIMENT 6

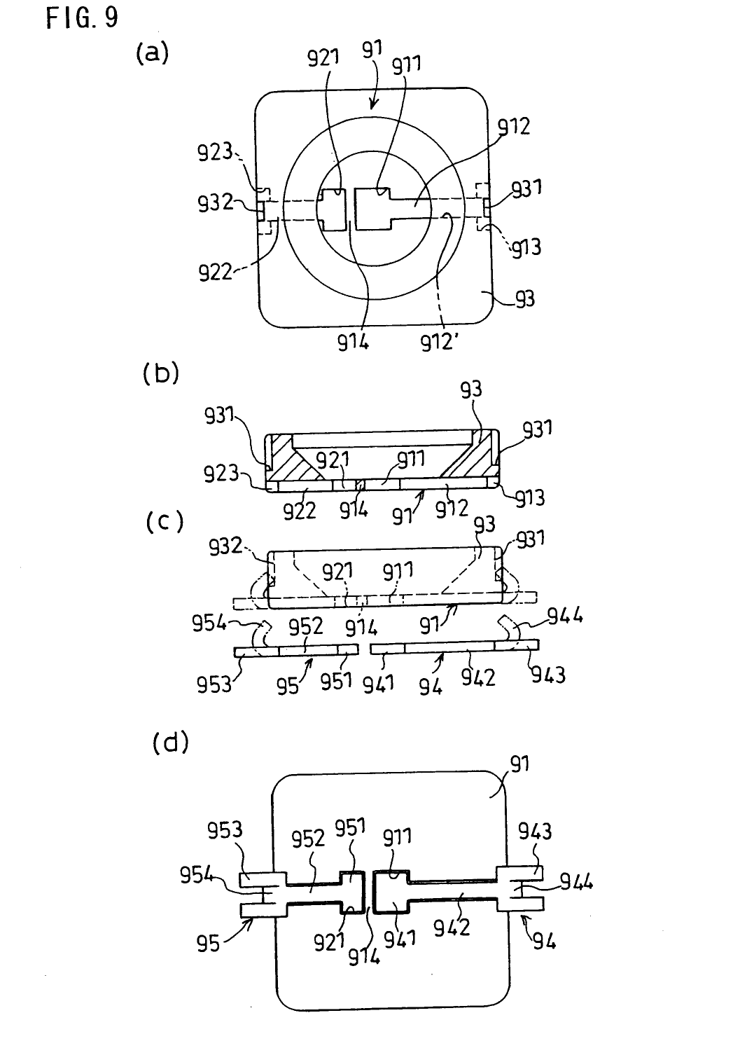

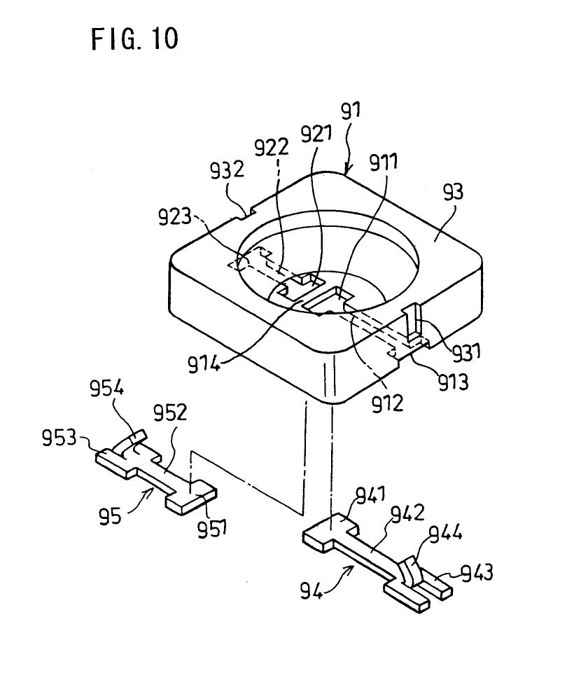

FIGS. 9(a) to (d) show a sixth example embodiment of the invention, with (a) being a plan view of the ceramic body formed integrally with the reflecting frame, (b) is a cross-sectional view of the ceramic body, (c) is a front view for explaining the light emitting diode package, and (d) is a bottom view of the light emitting diode package. FIG. 10 is an assembly perspective view for explaining the light emitting diode package in the sixth example embodiment of the invention. In FIGS. 9(a) to (d) and FIG. 10, the ceramic body 91 has a first opening 911, a more narrow, slender first lead opening 912 connected to the first lead opening 912, a recessed groove 912′ connected to the first lead opening 912 that is formed in the lower part of a reflecting frame 93, and a first open recess 913 connected to the recessed groove 912′ that is wider than the recessed groove 912′ at one outside end portion of the ceramic body 91, formed to be mutually connected.

Positioned opposite to the first opening 911 via a connecting portion 914, the ceramic body 91 has a second opening 921, a slender second lead opening and recessed groove 922 that is narrower than the second opening 921, and a second open recess 923 on the other outside end portion of the ceramic body 91 that is wider than the recessed groove 922. The reflecting frame 93 is integrally pre-formed with the ceramic body 91, and has high strength. After the ceramic body 91 is provided with the reflecting frame and each opening in the green sheet form, it is sintered into a ceramic.

The reflecting frame 93 is formed integrally with the ceramic body 91. The first opening 911 is positioned to be in the center of the ceramic body 91. The ceramic body 91 is provided on its outside end portion surface with an engaging recess 913 that engages with engaging portions 944 and 954 of lead-shaped mounting substrate 94 and lead-shaped connection substrate 95. In addition to the engaging portions 944 and 954 bent into a claw shape, the other ends of the lead-shaped mounting substrate 94 and lead-shaped connection substrate 95 are provided with electric power supply connection electrodes 943 and 953, as shown in the drawings.

In addition to insulating resin, the ceramic body 91 which includes the reflecting frame 93 may be made of alumina based ceramic. As an example, used in the ceramic body 91 was alumina system ceramic having a pore diameter of 0.10 μm to 1.25-μm, or a porosity of 10% or more. The reflecting frame 93 of the porous ceramic does not require the forming of a reflecting film, which makes it possible to improve the light reflectance by the irregular reflection of light by the inside surface.

In FIGS. 9(c) and (d) and FIG. 10, the lead-shaped mounting substrate 94 is fitted into the first opening 911 and the recessed grooves 912 and 913. The lead-shaped mounting substrate 94 is shaped to fit in the first opening 911, 912, 913. On the lead-shaped mounting substrate 94, the vertical electrode type light emitting diode mounting portion 941, lead portion 942, electric power supply connection electrode 943 which is wider than the lead portion 942, and claw-shaped engaging portion 944 formed by cutting two grooves in the electric power supply connection electrode 943 and bending the center part up are integrally connected. The way the engaging portion 944 is bent and its length and shape are such that, it can engage with the outside end portion on the ceramic body 91.

The lead-shaped connection substrate 95 fits in the second opening 921 and the recessed grooves 922 and 923. The lead-shaped connection substrate 95 is shaped to fit in the second opening 921 and the recessed grooves 922 and 923. On the lead-shaped connection substrate 95, the metal substrate connecting portion 951, described below, narrow lead portion 952, the electric power supply connection electrode 953 which is wider than the lead portion 952, and claw-shaped engaging portion 954 formed by cutting two grooves in the electric power supply connection electrode 953 and bending the center part up are integrally connected. The shape and the like of the engaging portion 954 are substantially counterparts to the engaging portion 944.

As shown in FIG. 9(c) and FIG. 10, the lead-shaped mounting substrate 94 and the lead-shaped connection substrate 95 fit in first opening 911 and recessed groove 912 and so forth, and are attached by engaging the engaging portions 944 and 954 from the underside of the ceramic body 91 with the engaging portion 931. The lower electrode of 2 the vertical electrode type light emitting diode is mounted on the vertical electrode type light emitting diode mounting portion 941 of the lead-shaped mounting substrate 94 via solder (not shown). Solder is placed on the upper part of the upper electrode (not shown) of the vertical electrode type light emitting diode, which is connected with the metal substrate connecting portion 951 of the lead-shaped connection substrate 95 by a metal member which is not shown. Then, the ceramic body 91 is passed through a reflow oven to heat the solder and bond the parts together.

The metal member that is not shown is, for example, a strip of gold ribbon, or ribbon plated with gold and/or silver. The metal member has low electrical resistance, so a large current flow can flow therethrough, it has good heat dissipation property, and the shape can be readily changed, making it easy to connect the electrodes. Because the metal member can have a large bonding area, it can be bonded by using solder instead of wire bonding.

The strip-shaped metal member has a thickness of from 15 μm to 35 μm, preferably 20 μm to 30 μm, and a width of 100 μm or more, and by making it not more than the width of the electrodes of the vertical electrode type light emitting diode, it can take a large current flow, heat dissipation property is improved and when made into an assembly it is stronger. When the thickness of the metal member was made thinner than 15 μm, the amount of current flow decreased and the heat dissipation effect was also less, so taking into consideration the electric current capacity and the heat dissipation effect, the present applicant determined that making the thickness more than 35 μm was a waste of material and there was a risk of defective connections arising due to the difficulty of bending it. Also, increasing the width of the strip-shaped metal member made it possible to take a large current flow and also enabled the heat dissipation effect to be utilized.

The metal member is nickel, aluminum or copper or an alloy of these, and if necessary, is plated with gold and/or silver. In addition to its use at bonding junctions, the plating enables light to be radiated efficiently, and applying it to eutectic soldering makes it possible to obtain a highly reliable light emitting device. Gold and/or silver plating at bonding junctions enables improved wettability of eutectic solder, improved electric current conductivity, and light reflectance to be achieved simultaneously. Also, the metal member may be a laminated substrate of nickel, aluminum or copper, or alloys thereof, and gold and/or silver.

If necessary, the upper part of the reflecting frame 93 can be provided with a fluorescent material containing film member (not shown). The fluorescent material containing film member can convert ultraviolet light radiating from the vertical electrode type light emitting diode to white light; an arbitrary fluorophore can be selected to obtain light of a desired color.

The lead-shaped mounting substrate 94, lead-shaped connection substrate 95, the electrodes of the vertical electrode type light emitting diode and the metal member are bonded using solder, such as for example eutectic solder. The bonding of the parts is normally done simultaneously by placing eutectic solder at prescribed bonding portions and passing them through a reflow oven. Because solder-based bonding of parts has high strength, there is no need for packing with sealing material to seal them.

The vertical electrode type light emitting diode is a blue light emitting diode or an ultraviolet, light emitting diode. In the case of a blue light emitting diode, substantially white light can be obtained by using a fluorescent film that includes fluorescent materials that absorb blue light and emit green and red light, and combining that with the blue light of the blue light emitting diode. Also, when the above light emitting element is an ultraviolet light emitting diode, substantially white light can be obtained by using a fluorescent film that includes fluorescent materials that absorb ultraviolet light and emit blue, green and red light, or substantially white light can be obtained even by using fluorescent materials that absorb ultraviolet light and emit blue light, or fluorescent materials that absorb the ultraviolet light and the blue light and emit green and red light.

### Example Embodiment 7

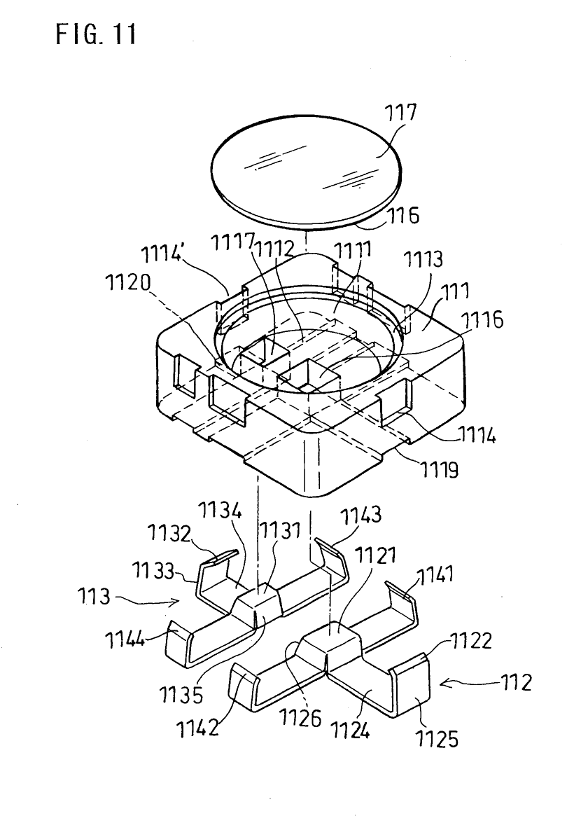

FIG. 11 is a schematic explanatory drawing of a seventh example embodiment of the invention, showing another example in which a lead-shaped metal mounting substrate and a lead-shaped connection substrate are fitted into openings in the ceramic body.

In the light emitting diode package, a light emitting diode mounting projection 1121 and a bonding projection 1131 of a first clip 112 and a second clip 113 are provided at both ends with engaging portions 1114 and 1114′ that resiliently engage with the molding 111. Also, the light emitting diode mounting projection 1121 and a bonding projection 1131 are provided with engaging portions 1141, 1142, 1143 and 1144 that resiliently engage with the molding 111 in mutually different directions that are orthogonal to the end portions thereof. The engaging portions 1141, 1142, 1143 and 1144 are formed folded inwards and resiliently engage with the molding 111. That is, the light emitting diode mounting projection 1121 and the bonding projection 1131 are made to engage with the molding 111 at three points, so the mounting is secure and stable.

### EXAMPLE EMBODIMENT 8

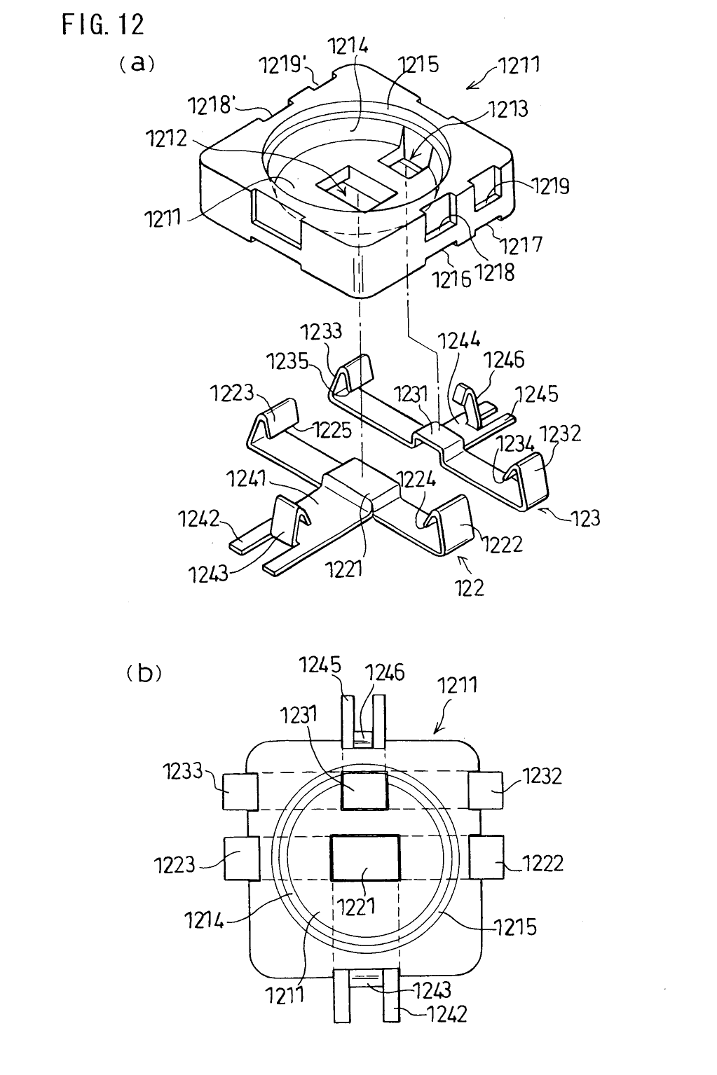

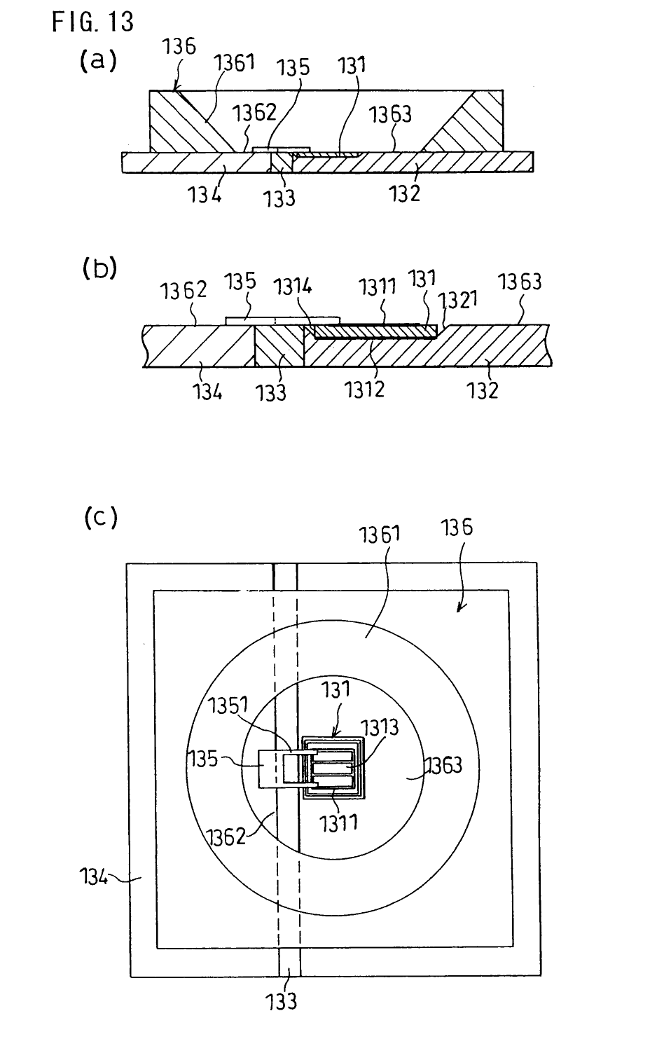

FIGS. 12(a) and (b) are schematic explanatory drawings of an eighth example embodiment of the invention, showing another example in which a lead⁻shaped metal mounting substrate and a lead-shaped connection substrate are fitted into the openings in the ceramic body.

In FIGS. 12(a) and (b), ceramic body 1211 has an opening 1212 and an opening 1213, and a reflecting frame 1214 formed integrally therewith. The openings 1212 and 1213 comprise a narrow portion and a wide portion. Also, the openings 1212 and 1213 communicate with recessed grooves 1216 and 1217 provided in the lower part. The side portion of the reflecting frame 1214 is provided with engaging recesses 1218, 1218′, 1219 and 1219′ with which the engaging projections 1224, 1225, 1234 and 1235 of the lead-shaped metal mounting substrate 122 and the lead-shaped metal connection substrate 123 engage.

The lead-shaped metal mounting substrate 122 has a light emitting diode mounting projection 1221 in the center portion thereof, and via a horizontal portion that extends horizontally, is equipped with engaging projection pieces 1222 and 1223. The ends of the engaging projection pieces 1222 and 1223 are folded over to form the engaging projections 1224 and 1225. The lead-shaped metal connection substrate 123 has a connection projection 1231 that connects the metal member to the upper electrode of the light emitting diode substantially in the center portion thereof, and via a horizontal portion that extends horizontally, is equipped with engaging projection pieces 1232 and 1233. The ends of the engaging projection pieces 1232 and 1233 are folded over to form the engaging projections 1234 and 1235.

The area of the light emitting diode mounting projection 1221 is larger than that of the bonding projection 1231. Formed on the light emitting diode mounting projection 1221 and the bonding projection 1231 are horizontal portions 1241 and 1243 hat extend in mutually different directions that are orthogonal to the direction in which the engaging projecting pieces 1222, 1223, 1232 and 1233 extend. A part of the horizontal portions 1241 and 1243 is used to form electric power supply terminals 1242 and 1245, formed, for example, by bending the central portion to form engagement pieces 1243 and 1246.

Because both ends of the lead-shaped metal mounting substrate 122 and the lead-shaped metal connection substrate 123 are provided with flat electric power supply terminals 1242 and 1245, and engagement pieces 1243 and 1246, with the engaging projecting pieces 1222, 1223, 1232 and 1233, engagement is effected at three places, and the distance to connect the power supply can be minimized.

### COMPARATIVE EXAMPLE

The tensile strength of the gold wire in a prior art example is here compared with that of the gold ribbon of this invention. In the test, the center of gold wire and gold ribbon was pulled, and the force gradually increased. A strand of conventional gold wire 30 μm in diameter broke near the bonding portion when the force was 11 grams. It was determined that because the conventional jointing method did not use soldering, there was a weak point in the vicinity of the gold wire bonding connection. Similarly, in a tensile test of 25 μm diameter, the gold wire broke in the vicinity of the connection when the force was 7 grams. When the gold ribbon of this invention was used having a width of 200 μm and a thickness of 25 μm, it broke under a tensile force in the region of 100 grams to 150 grams.

The metal member 15 is, for example, thin strips of gold ribbon, or copper ribbon or thin sheet plated with gold and/or silver. Having low electrical resistance, the metal member can take a large current flow, has good heat dissipation, and the shape thereof can be readily changed, facilitating connection with electrodes. Also, with the metal member the bonding area can be made larger, making it possible to use solder instead of wire bonding, enabling damage to the light emitting element and bonding portions from vibration to be prevented.

The thin strip shaped metal member has a thickness of from 15 μm to 35 μm, preferably 20 μm to 30 μm, and a width of 80 μm to 1000 μm, preferably 100 μm to 500 μm, making it possible to run a large current to the vertical electrode type light emitting diode, increase the heat dissipation property, and increase the strength when made into an assembly.

When the thickness of the metal member is made thinner than 15 μm, the amount of electric current that can flow therein is reduced and the heat dissipation effect is less, taking into consideration the electric current capacity and the heat dissipation effect of the thickness, the present applicant determined that making it thicker than 35 μm would be a waste of material and there was a risk of defective connections arising due to the difficulty of bending it. Also, by increasing the width of the strip shaped metal member, it is possible to take a large current flow and to utilize the heat dissipation effect.

The metal member may be nickel, aluminum or copper, or an alloy of these, and if necessary, is plated with gold and/or silver. In addition to its use in junctions, the plating enables light to be radiated efficiently, and applying it to solder processing makes it possible to obtain a highly reliable light emitting device. Gold and/or silver plating at bonding junctions provides improved wettability of solder, improved electric current conductivity, and light, reflectance to be achieved simultaneously. Also, the metal member may be a laminated substrate of nickel, aluminum or copper, or alloys thereof, and gold and/or silver.

An n-type semiconductor layer, an active layer and an upper electrode are provided on the ceramic molding or the ceramic substrate of the vertical electrode type light emitting diode. The size of the vertical electrode type light emitting diode is, for example, 1.0 mm by 1.0 mm, 0.7 mm by 0.7 mm, 0.5 mm by 0.5 mm, or 0.3 mm by 0.3 mm, and the thickness is 0.15 mm.

The vertical electrode type light emitting diode is a blue light emitting diode or an ultraviolet light emitting diode. In the case of a blue light emitting diode, substantially white light can be obtained by using a fluorescent film that includes fluorescent materials that absorb blue light and emit green and red light, and combining that with the blue light of the blue light emitting diode. Also, when the light emitting element 12 is an ultraviolet light emitting diode, substantially white light can be obtained by using a fluorescent film that includes fluorescent materials that absorb ultraviolet light and emit blue, green and red light, or substantially white light can be obtained even by using fluorescent materials that, absorb ultraviolet light and emit, blue light, or fluorescent materials that absorb the ultraviolet light, and the blue light and emit green and red light.

Although details of example embodiments of the invention have been described in the foregoing, the invention is not, limited to the above example embodiments. Various design modifications may be made to the extent that such modifications do not depart from the scope of the matter described in the scope of the patent claims herein. In the example embodiments, the number of vertical electrode type light emitting diodes in the package may be increased and connected in parallel between the first clip and second clip, or a third clip or the like may be added to connect the vertical electrode type light emitting diodes in series. The fluorescent layers and gallium nitride system vertical electrode type light emitting diode used in this invention may be ones that are publicly known or well-known. Publicly known or well-known ceramics and heat-resistant synthetic resins may be used for the molding of the invention. There is no particular limitation on the clips of the invention, as long as they can be press-formed and have springiness.

1. A package for a light emitting diode characterized in that it comprising:
a ceramic body comprising a reflecting frame, a substrate formed integrally in the reflecting frame, at least two openings provided in the substrate, and a recessed groove that communicates with a lower side end portion; and
a lead-shaped metal substrate that fits in each opening and/or the recessed groove.

2. A package for a light emitting diode according to claim 1, wherein a recess or a projection formed on an outside end portion of the ceramic body engages with a claw portion provided on an outside of the lead-shaped connection substrate.

3. A package for a light emitting diode as described in claim 1 or claim 2, wherein the lead-shaped metal substrate is resiliently maintained between the opening and the outside end of the ceramic body.

4. A package for a light emitting diode comprising at least:
a ceramic molding that integrally comprises a reflecting frame, a first engaging portion and a second engaging portion provided on a side portion of the reflecting frame, a bottom portion formed inside the reflecting frame, and a first opening and a second opening provided in the bottom portion,
a first conductive member comprising a first catch portion at one end that engages with the first engaging portion, a projecting portion formed with a projecting cross-section on another end that fits in the first opening, and a horizontal portion that extends along a lower part of the ceramic molding between the projecting portion and the first catch portion, and
a second conductive member comprising a projecting portion formed with a projecting cross-section on one end that fits in the second opening, a second catch portion on another end engaged with the second engaging portion, and a horizontal portion that extends along a lower part of the ceramic molding between the projecting portion and the second catch portion.

5. A package for a light emitting diode comprising at least:
A ceramic substrate formed with a first opening and a second opening,
a first conductive member comprising a first catch portion at one end that engages with a side end portion of the ceramic substrate, a projecting portion formed with a projecting cross-section on another end that fits in the first opening, and a horizontal portion that extends along a lower part of the ceramic substrate between the projecting portion and the first catch portion, and
a second conductive member comprising a projecting portion formed with a projecting cross-section on one end that fits in the second opening, a second catch portion on another end engaged with a side end portion of the ceramic substrate, and a horizontal portion that extends along a lower part of the ceramic substrate between the projecting portion and the second catch portion.

6. A package for a light emitting diode comprising at least:
a ceramic molding having a ceramic substrate or a reflecting frame in which at least two or more sets comprising pairs of openings are formed in series,
a first conductive member comprising a first catch portion at one end engaged with one of the ceramic substrate or the ceramic molding, a projecting portion formed with a projecting cross-section at another end that fits in a first opening, and a horizontal portion that extends along a lower part of the ceramic substrate or the ceramic molding between the projecting portion and the first catch portion,
a second conductive member comprising a projecting portion formed with a projecting cross-section on one end that fits in a second opening adjoining the first opening, a projecting portion formed with a projecting cross-section that fits in a third opening adjoining the second opening, and a horizontal portion that extends along a lower part of the ceramic substrate or the ceramic molding between adjacent projecting portions, and
a second catch portion formed on another end of a conductive member that is a last of a desired number of openings and conductive members that are connected.

7. A package for a light emitting diode comprising at least:
a ceramic molding having a ceramic substrate or a reflecting frame in which at least two or more sets comprising pairs of first openings and second openings are formed in parallel,
a first conductive member comprising a first catch portion engaged with said one at one end, a projecting portion formed with a projecting cross-section at another end that fits in the first opening, and a horizontal portion that extends along a lower part of the ceramic substrate or the ceramic molding between the projecting portion and the first catch portion,
a second conductive member comprising a projecting portion formed with a projecting cross-section on one end that fits in the second opening, a second catch portion on another end engaged with a second engaging portion, and a horizontal portion that extends along a lower part of the ceramic molding between the projecting portion and the second catch portion, and
unit light emitting portions each comprised of the first conductive member composed of the first catch portion, the first opening, and the projecting portion, the second conductive member composed of the second opening and the projecting portion, and the second catch portion are provided in parallel.

8. A package for a light emitting diode as described in any one of claims 1 to 7, wherein the ceramic substrate or the ceramic molding is formed with an opening, and the conductive member formed in a projecting cross-section is fitted in each opening to form a surface light source.

9. A package for a light emitting diode as described in any one of claims 1 to 8, wherein a claw-shaped catch portion is formed on one end or another end of the conductive member.

10. A package for a light emitting diode as described in any one of claims 1 to 9, characterized in that the conductive member is a plate-like member bent so that one end or another end is provided with at least one downward facing projecting portion having a cross-section in a shape of a [symbol] character.

11. A package for a light emitting diode as described in any one of claims 1 to 9, wherein the projecting portion having a cross-section in a shape of a [symbol] character on the conductive member is provided with pendant portions at front and back and each side.

12. A package for a light emitting diode as described in any one of claims 1 to 11, wherein the conductive member is resiliently maintained between the opening and the outside end portion of the ceramic molding or the ceramic substrate.

13. A package for a light emitting diode as described in any one of claims 1 to 12, wherein a recessed groove is formed in an underside of the ceramic molding or the ceramic substrate into which the horizontal portion of the conductive member fits.

14. A package for a light emitting diode comprising at least:
a molding integrally formed with a bottom portion having at least a first opening and a second opening, a reflecting portion that reflects light, and a fluorescent film member mounting portion for mounting a fluorescent film member,
a first clip having a light emitting diode mounting projection that fits in the first opening and which resiliently engages with the molding at both ends thereof, and
a second clip having a bonding projection that fits in the second opening and which resiliently engages with the molding at both ends thereof.

15. A package for a light emitting diode as described in any one of claims 1 to 14, wherein the bottom portion of the molding is provided with a recessed groove portion in which the first clip and the second clip, or the first conductive member and the second conductive member fit.

16. A package for a light emitting diode as described in any one of claims 1 to 15, wherein the side portion of the molding is provided with a recessed groove portion with which the first clip and the second clip, or the ends of the first conductive member and second conductive member engage.

17. A package for a light emitting diode as described in any one of claims 1 to 16, wherein both ends of the first clip and the second clip, or the first conductive member and the second conductive member, are folded inward to form inclined projections.

18. A package for a light emitting diode as described in any one of claims 1 to 17, wherein both ends of the first clip and the second clip, or the first conductive member and the second conductive member, are provided with electric power supply terminals.

19. A package for a light emitting diode as described in any one of claims 14 to 18, characterized in that at both ends of the bottom portion, the electric power supply terminals project in mutually different directions.

20. A package for a light emitting diode as described in any one of claims 1 to 19, wherein the molding is formed of ceramic, porous ceramic or heat-resistant synthetic resin.

21. A package for a light emitting diode as described in any one of claims 1 to 20, wherein both ends of the first clip and the second clip, or the first conductive member and the second conductive member, are folded inward to form inclined projections.

22. A package for a light emitting diode as described in any one of claims 1 to 21, wherein the first clip and the second clip, or the first conductive member and the second conductive member, are formed in three directions centering on the light emitting diode mounting projection and the bonding projection so that they do not hit against each other, and have engaging portions for resilient engagement with the molding.

23. A package for a light emitting diode as described in any one of claims 1 to 22, characterized in that portions of the engaging portions are formed into flat electric power supply terminals.

24. A light emitting device comprises at least:
a ceramic body comprising a reflecting frame, a substrate formed integrally inside the reflecting frame, at least two openings formed in the substrate, and a recessed groove that extends from the openings to the outside ends,
a lead-shaped metal mounting substrate that is fitted in one opening and/or recessed groove,
a lead-shaped metal connection substrate that is fitted in another opening and/or the recessed groove,
a vertical electrode type light emitting diode having a lower electrode bonded to the lead-shaped metal mounting substrate,
a metal member that connects an upper electrode of the vertical electrode type light emitting diode and the lead-shaped metal connection substrate, and
solder used to bond the lead-shaped metal mounting substrate and the lower electrode of the vertical electrode type light emitting diode, to bond the upper electrode of the vertical electrode type light emitting diode and the metal member, and to bond the metal member and the lead-shaped metal connection substrate.

25. A light emitting device described in claim 24, wherein the lead-shaped metal mounting substrate and the lead-shaped metal connection substrate extend to a lower part in a vicinity of the ends of the ceramic body.

26. A light emitting device described in claim 25, wherein the ceramic body comprises an inside opening having a wide area, an opening having a narrow area provided in a vicinity of the opening having the wide area, a recessed groove formed in a lower part of the reflecting frame that communicates with the opening having the narrow area, and a recessed groove having a wide area that extends to the outside end communicated with the opening having the wide area.

27. A light emitting device as described in either of claims 25 and 26, wherein a mounting region in the lead-shaped metal mounting substrate and the lead-shaped metal connection substrate on which the vertical electrode type light emitting diode is mounted and a connection region that connects the metal member, fit in the opening having the wide area formed in the ceramic body by the resilience of each of the end portions of the lead-shaped metal mounting substrate and the lead-shaped metal connection substrate in the outside end of the ceramic body.

28. A light emitting device comprising at least:
a ceramic molding that integrally comprises a reflecting frame, a first engaging portion and a second engaging portion provided on a side portion of the reflecting frame, a bottom portion formed inside the reflecting frame, and a first opening and a second opening provided in the bottom portion,
a first conductive member comprising a first catch portion at one end engaged with the first engaging portion, a projecting portion formed with a projecting cross-section on another end that fits in the first opening, and a horizontal portion that extends along a lower part of the ceramic molding between the projecting portion and the first catch portion,
a second conductive member comprising a projecting portion formed with a projecting cross-section on one end that fits in the second opening, a second catch portion on another end engaged with the second engaging portion, and a horizontal portion that extends along a lower part of the ceramic molding between the projecting portion and the second catch portion,
a vertical electrode type light emitting diode having a lower electrode bonded on the projecting portion provided on the first conductive member,
a metal member that connects an upper electrode of the vertical electrode type light emitting diode and the projecting portion provided on the second conductive member,
solder used to bond the projecting portion provided on the first conductive member and the lower electrode of the vertical electrode type light emitting diode, and to bond the upper electrode of the vertical electrode type light emitting diode and the metal member, and the metal member and the projecting portion provided on the second conductive member, and
a fluorescent material containing film member provided on an upper opening of the reflecting frame.

29. A light emitting device comprising at least:
a ceramic substrate having a first opening and a second opening, a first conductive member comprising a first catch portion at one end that engages with a side end portion of the ceramic substrate, a projecting portion formed with a projecting cross-section on another end that fits in the first opening, and a horizontal portion that extends along a lower part of the ceramic substrate between the projecting portion and the first catch portion,
a second conductive member comprising a projecting portion formed with a projecting cross-section on one end that fits in the second opening, a second catch portion on another end engaged with a side end portion of the ceramic substrate, and a horizontal portion that extends along a lower part of the ceramic substrate between the projecting portion and the second catch portion,
a vertical electrode type light emitting diode having a lower electrode bonded on the projecting portion provided on the first conductive member and having fine ridges formed on a light emitting surface thereof,
a metal member that connects an upper electrode of the vertical electrode type light emitting diode and the projecting portion provided on the second conductive member,
solder used to bond the projecting portion provided on the second conductive member and the lower electrode of the vertical electrode type light emitting diode, and to bond the upper electrode of the vertical electrode type light emitting diode and the metal member, and the metal member and the projecting portion provided on the second conductive member, and
a cover member that covers the vertical electrode type light emitting diode via an interposed space, and is formed with its surface being wholly covered by fluorescent material containing film member.

30. A light emitting device described in claim 29, wherein the cover member wholly covers the vertical electrode type light emitting diode and has a fluorescent material containing film member formed over its whole surface.

31. A light emitting device described in claim 28 or 29, wherein the ceramic molding, the ceramic substrate and the conductive member are bonded by adhesive.

32. A light emitting device described in any one of claims 29 to 31, wherein a lead-shaped metal mounting substrate and a lead-shaped metal connection substrate are bonded to the ceramic body by adhesive.

33. A light emitting device described in any one of claims 24 to 32, wherein the metal member is gold wire formed into a ribbon shape.

34. A light emitting device described in any one of claims 24 to 32, wherein the metal member is copper formed into a ribbon shape that is plated with nickel, gold and/or silver.

35. A light emitting device described in any one of claims 24 to 34, wherein the metal member has a thickness of from 15 μm to 35 μm, preferably 20 μm to 30 μm, and a width of from 100 μm up to a width of electrodes of the vertical electrode type light emitting diode.

36. A light emitting device described in any one of claims 24 to 35, wherein the ceramic is composed of porous ceramic.

37. A light emitting device comprising at least:
a molding integrally formed with a bottom portion having at least a first opening and a second opening, a reflecting portion that reflects light, and a fluorescent film member mounting portion for mounting a fluorescent film member,
a first clip having a light emitting diode mounting projection that fits in the first opening and which resiliently engages with the molding at both ends thereof,
a second clip having a bonding projection that fits in the second opening and which resiliently engages with the molding at both ends thereof,
a vertical electrode type light emitting diode having a lower electrode bonded on the light emitting diode mounting projection,
metal ribbon that connects an upper electrode of the vertical electrode type light emitting diode and the bonding projection, and
a fluorescent film member mounted on the opening of the molding.

38. A light emitting device described in claim 37, wherein a bonding of the light emitting diode mounting projection and the lower electrode of the vertical electrode type light emitting diode, the upper electrode of the vertical electrode type light emitting diode and the metal ribbon, and the metal ribbon and the bonding projection is solder.

39. A light emitting device comprising at least:
a molding integrally formed with a bottom portion having at least a first opening and a second opening, a reflecting portion that reflects light, a fluorescent film member mounting portion for mounting, and a fluorescent film member,
a first clip having a light emitting diode mounting projection that fits in the first opening and which resiliently engages with the molding at both ends thereof,
a second clip having a bonding projection that fits in the second opening and which resiliently engages with the molding at both ends thereof,
a vertical electrode type light emitting diode having a lower electrode bonded on a light emitting diode mounting projection,
a metal ribbon that connects an upper electrode of the vertical electrode type light emitting diode and the bonding projection, and
a fluorescent film member mounted on the opening of the molding.

40. A light emitting device described in claim 39, wherein a bonding of the light emitting diode mounting projection and the lower electrode of a vertical electrode type light emitting diode, the upper electrode of the vertical electrode type light emitting diode and the metal ribbon, and the metal ribbon and the bonding projection is solder.

41. A light emitting device described in claim 35 or 40, wherein a space between the vertical electrode type light emitting diode and the fluorescent film member is an air layer.

42. A method of manufacturing a light emitting device comprising the steps at least of:
a package fabrication step of integrally forming in a ceramic body a reflecting frame, a substrate formed inside the reflecting frame, at least two openings provided in the substrate, and a recessed groove that extends from the openings to the outside ends, and fitting a resilient lead-shaped metal mounting substrate and a lead-shaped metal connection substrate in respective openings, the recessed groove and the outside end portions, and
a light emitting component fabrication step of placing solder between a lower electrode of a vertical electrode type light emitting diode and the lead-shaped metal connection substrate, and between an upper electrode of the vertical electrode type light emitting diode and the lead-shaped metal connection substrate, and a metal member, followed by heating of the ceramic body, the lead-shaped metal mounting substrate, the lead-shaped metal connection substrate the vertical electrode type light emitting diode and the metal member.

43. A method of manufacturing a light emitting device described in claim 42, wherein a fluorescent material containing film member is provided on the reflecting frame after completion of the package fabrication step and the light emitting component fabrication step.

44. A method of manufacturing a light emitting device comprising the steps at least of:
a package fabrication step of forming in a ceramic body or a ceramic substrate that forms a reflecting frame at least two openings, and fitting a conductive member provided with a projecting cross-sectional portion and engaging claw portions in the openings and an engaging portion, and
a light emitting component fabrication step of using solder to bond between a lower electrode of a vertical electrode type light emitting diode having fine ridges formed on a light emitting surface and a projecting cross-sectional portion provided on the conductive member, between an upper electrode of the vertical electrode type light emitting diode and the metal member, and between the metal member and a projecting cross-sectional portion on another conductive member, followed by heating of the ceramic body or the ceramic substrate, the conductive members, the metal member and the vertical electrode type light emitting diode, followed by cooling after the solder has melted.

45. A method of manufacturing a light emitting device described in claim 44, wherein following completion of the package fabrication step and light emitting component fabrication step, a cover member is provided on the reflecting frame on which a fluorescent material containing film member is formed via an space portion.
